(19) United States
(12) Patent Application Publication
(10) Pub. No.: US 2004/0253816 A1
(43) Pub. Date: Dec. 16, 2004

(54) High resolution patterning method

(76) Inventors: William Norman Damerell, Hants (GB); Anthony William Kynaston-Pearson, Hants (GB); Daniel Robert Johnson, Malver Worcs (GB)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 10/494,156

(22) PCT Filed: Oct. 25, 2002
(86) PCT No.: PCT/GB02/04864

(30) Foreign Application Priority Data
Oct. 29, 2001 (GB) 0125883.9

(51) Int. Cl. H01L 21/44

(52) U.S. Cl. 438/674; 438/687

(57) ABSTRACT

This invention relates to a method of forming high resolution patterns of material on a substrate by way of catalytic reactions.

This invention relates to a method of forming high resolution patterns of material on a substrate and encompasses the fields of catalytic reactions (especially autocatalytic coating methods) and also writing methods using energetic media.

“Beam Writing” refers to the technique of directly depositing a material onto a substrate using an energetic media such as a laser, AFM (Atomic Force Microscope), STM (Scanning Tunnelling Microscope), ion, atom or electron beam. This technique is capable of depositing any material, e.g. a metal, onto the target substrate as narrow patterns or lines (see Introduction and Physical methods of film deposition, Sections I and II pp 3-207 and Physical-Chemical methods of film deposition, Section IV pp 335-396; Thin Film processes (1978); Publishers Academic Press: Also Chapter. 1 in Handbook of Thin Film Technology (1970), R. Glang. Publishers McGraw-Hill).

Autocatalytic plating is a form of electrode-less (electroless) plating in which a metal is deposited onto a substrate via a chemical reduction process. The advantage of this technology is that an electric current is not required to drive the process and so electrical insulators can be coated. Coatings derived by this technique are usually more uniform and adherent than from other processes and can be applied to unusually shaped surfaces (see Deposition of Inorganic Films from Solution, Section III Ch 1 pp 209-229; Thin Film processes (1978); Publishers Academic Press and, Smithells Metals Reference Book, 7^{th} Edition (1992) Chapter 32, pp12-20; Publishers Butterworth Heinmann.)

Processes exist for the autocatalytic deposition of a large number of metals, particularly cobalt, nickel, gold, silver and copper from a suitable solution bath. Basically, the solutions contain a salt of the metal to be deposited and a suitable reducing agent, e.g. hypophosphite, hydrazine, borane etc. When a metal substrate, which is catalytic to the reaction, is introduced into the solution bath it becomes covered with a layer of the coating metal which itself is catalytic so that the reaction can continue.

Deposition will only occur if conditions are suitable on the substrate to initiate and then sustain the autocatalytic process. Therefore in cases where the substrate is a plastic or ceramic, for example, additional steps are required to create suitable surface properties. Usually, in such cases the substrate is “sensitised” with a reducing agent, e.g. SnCl₂. Also, the surface may be “activated” with a thin layer of an intermediate catalytic material, e.g. Palladium (itself a candidate metal for autocatalytic deposition), in order to aid the deposition process. Such “deposition promoting materials” are generally referred to in the literature as “sensitisers” and “activators” respectively.

Autocatalytic deposition is generally employed to coat whole surfaces. However, in order to form metal patterns, e.g. for electrical circuits or decorative effects, additional processes such as photolithography followed by etching of surplus metal have to be performed. There are disadvantages to these additional processes, including inflexibility, long lead times, increased costs and the use of excessive materials to provide coatings much of which is then subsequently removed as waste.

There are many types of catalytic reaction (including the autocatalytic reaction described above) that can take place over the surface of a substrate material and such reactions can be used to increase the rate of or activate reactions in gas, liquid or solid environments.

The “catalytic materials” that are used in such reactions include “deposition promoting materials” (as defined above) but also include other heterogeneous catalysts and homogeneous catalysts. Heterogeneous catalytic materials include metals such as platinum, rhodium and palladium and metal oxides containing catalytic sites, e.g. perovskite cage structures. These catalysts are used in synthetic or decomposition reactions in organic or inorganic chemistry, for example in the Fischer-Tropsch synthesis of organic molecules, petrochemical cracking or in the decomposition of hydrocarbons. Homogeneous catalytic materials include enzymes which are used, for example in biochemical testing in diagnostic arrays and for decompositional analysis of biopoloymers and systems that mimic proteozone behaviour. Homogeneous catalysts also include negative catalysts, commonly known as inhibitors, which moderate reactions.

Generally in such reactions the catalytic material used is either applied to or is effective over the whole of the substrate material and as a consequence the reaction takes place over the whole of the substrate.

It is therefore an object of the present invention to provide a method of preparing a substrate material such that it is capable of initiating a catalytic reaction over a predetermined area of its surface that alleviates some of the above-mentioned disadvantages.

Accordingly, this invention provides a method of preparing a substrate so that it is capable of sponsoring a catalytic reaction over a pre-determined area of its surface comprising the step of coating some or all of the substrate material with a catalytic material (as hereinbefore defined), wherein a “beam writing” process (as hereinbefore defined) is used to physically transport catalytic material onto the surface of the substrate such that the catalytic material is deposited onto the substrate in a predetermined pattern.

The substrate, which may be any material, for example, metal(s), organic/inorganic compounds, ceramics or polymers, is thus initially treated with a catalyst material that will allow the substrate to sponsor a catalytic reaction. For example, if the catalyst material is a deposition promoting material then the substrate will be capable of being metal plated via an autocatalytic process. In general terms the catalysed surface may be exposed to any reaction environment, including gas, vapour, liquid, solution or solid.

A beam writing process is used to directly deposit the catalytic material onto the substrate. The use of such a process allows the deposited material to be put down in any user-defined pattern. There are a number of ways in which a beam writing process (as defined above) could deposit material onto the surface.

Beams of for example light, electrons or ionised gas may be used to ablate material from a source comprising inorganic materials such as oxides, salts, metals or semiconductors, or alternatively organic materials such as polymers. The materials may then deposit onto a substrate in a user-defined pattern either by employing “shadow masks” or writing mechanisms.

Alternatively, material may be contained within a beam of plasma. Such a plasma could be constrained in a suitable arrangement of magnetic and/or electric fields such that it forms a narrow beam. This beam could be moved over the surface thereby depositing the required material.

Alternatively, a device such as an ATM or STM could physically move atoms or molecules into place on the surface in the desired pattern.

In a still further alternative, a focused ion beam is used to deposit material onto the substrate. In this case a source of the catalytic material is ionised and then directed to the surface of the substrate by an arrangement of electrostatic lenses.

The materials themselves are chosen such that they are capable of sponsoring a subsequent catalytic reactions. For example, in the case of the electroless deposition of copper metal, it is possible to deposit a thin layer of the metal by electron beam deposition. The metal coated substrate may then be placed into an autocatalytic deposition bath solution of copper and further copper metal will deposit to a greater thickness on the whole pattern at the same time by autocatalytic deposition. Here the beam written copper is acting as a deposition promoting material. The advantages of this method to the current example are that the writing processes can be used to produce very fine patterns of metal which can be built in thickness more readily using an electroless deposition process.

Therefore, once treated, the substrate is immersed into a suitable catalytic reaction environment, such as a liquid bath, and a catalytic reaction occurs over only those areas of the substrate that contain catalytic material that was deposited by the beam writing process. Since the reaction occurs only within the pre-determined pattern there is a reduction in waste material compared to existing techniques and no requirement for further processing, e.g. by etching, in order to create the desired pattern.

Certain catalytic reactions will result in material being deposited onto the prepared substrate from the catalytic reaction solution and in such cases the process according to the invention can be repeated in order to build up multiple material layers/patterns. Insulator layers can also be added to separate these different layers, for example by a pattern transfer mechanism such as ink jet printing.

The resolution of the deposited material patterns is limited only by the characteristics of the writing process.

Catalytic material may also be written into subsurface substrate features, for example holes grooves and pits of various shapes. The substrate features may be formed by a feature forming mechanism for example a scriber or drill, which employs energetic beams (e.g. laser or electron beam) or alternatively a mechanical device. Where it is preferable to write the catalytic material into the substrate feature and not the surrounding areas of substrate the writing mechanism may be coupled to the feature forming mechanism to align the writing and scribing mechanisms. The writing process may therefore follow momentarily after the feature forming process. Similarly the surface feature may be a protrusion such as a bump or embossed feature, created either by the laying down of material (e.g. by a print transfer mechanism) or alternatively by a moulding tool acting on the substrate. Once again the writing mechanism may be aligned with these features should the requirement be to write onto these and not the surrounding material.

Autocatalytic reactions are used to deposit metal onto a substrate. Such processes are generally used to deposit whole surfaces. However, the process according to the present invention can be used to deposit metal patterns in a pre-determined user defined manner. To deposit a metal coating the catalytic material is chosen to be a deposition promoting material. The prepared substrate in this case will then be suitable for subsequent metal plating by immersion in a suitable autocatalytic deposition solution.

The metal coating which is deposited by the autocatalytic deposition process onto the pattern put down by the beam writing process may subsequently be coated with further metals through electroless deposition, provided the first autocatalytically deposited metal coating surface can catalyse or ion exchange with the subsequent metals. For example the exposed areas of a sensitised substrate may be autocatalytically coated with a layer of nickel which could then be further coated, via a further electroless process, with a coating of copper. Alternatively, if the first electroless coating is copper a further coating of tin maybe deposited.

It is also possible for the autocatalytic deposition solution to contain two different metal salts which are then co-deposited onto a sensitised substrate at the same time, for example nickel and copper.

An autocatalytically deposited metal pattern may also be further coated with a wide range of metals or compounds by electrodeposition, provided there are continuous electrical paths in the pattern to act as the cathode of an electrolytic bath. An example is the electrodeposition of “chromium” plate onto nickel to prevent tarnishing.

The deposition promoting material may comprise a reducing agent (a “sensitiser”) for example a salt like SnCl₂, onto which metals like silver can be reduced from an autocatalytic solution.

As an alternative to, or as well as, a reducing agent, the deposition promoting material could be an activator such as an autocatalytic metal. For example palladium, cobalt, nickel, or copper could be added to the beam writing process to catalyse a particular metal deposition.

As a further alternative, the deposition promoting material could be one that is able to ion exchange with the catalytic material contained within the autocatalytic solution bath. For example, Ni, Pd or Fe could be added directly to the beam writing process. Once the coated substrate is introduced into the autocatalytic solution bath the deposition promoting material undergoes ion exchange with the metal in the autocatalytic solution, thereby nucleating deposition of the electroless coating.

In these example the deposition promoting material is deposited using a beam writing method e.g. electron or laser beam.

Where a chemical reducing agent is deposited onto a substrate to become the deposition promoting agent, the method may conveniently comprise a further step of immersing the now “sensitised” substrate into an intermediate solution bath of reducible metal ions (prior to the final autocatalytic solution bath), to provide an “activating” metal overlayer on the deposition promoting agent. This further step has the effect of aiding the deposition promoting material and promoting easier deposition of certain metals (such as copper, nickel and cobalt).

For example, for the case of SnCl₂ as the deposition promoting material, once the substrate material has had the SnCl₂ applied to it, it can be immersed into an intermediate solution bath comprising a dilute aqueous solution of PdCl₂. This causes the deposition of Pd metal onto the areas of the substrate coated with the deposition promoting material. If the Pd “activated” substrate is now immersed into an autocatalytic solution then autocatalytic deposition will take place onto the Pd metal. Such an intermediate step is useful in cases where the metal to be deposited from the autocatalytic deposition bath is either copper, nickel or cobalt.

As an alternative to the above the deposition promoting material could be formed by beam writing a metal containing compound onto the substrate and then immersing the substrate into a solution of a chemical reducing agent. For example, the beam writing process could contain PdCl₂. Following deposition of this onto the substrate, an intermediate step could be to convert the PdCl₂ on the surface of the substrate to Pd metal by immersion in a dilute aqueous solution of SnCl₂.

In a further alternative, the intermediate step could be omitted by using a “reducing” gas, for example hydrogen or carbon monoxide in the writing environment. In such cases a metal salt could be reduced whilst being beam written onto the substrate, for example, a metal salt like PdCl₂ could be reduced by a reducing gas to form Pd metal as the deposition promoting material. Equally, a reducing agent may be beam written in conjunction with the metal salt to achieve the same effect. Following deposition of the reduced metal species the substrate could then be introduced immediately into the autocatalytic deposition solution to deposit the metal of choice. It will therefore be clear to the skilled man that a deposition promoting material may be created by more than one material being present during the beam writing process which materials interact and/or combine to produce a deposition promoting material suitable for this purpose.

Conveniently the substrate may incorporate a porous layer which can influence the adhesion, scratch resistance and texture of the subsequent electroless metal coating.

Embodiments of the present invention will now be described with reference to the accompanying drawings in which:

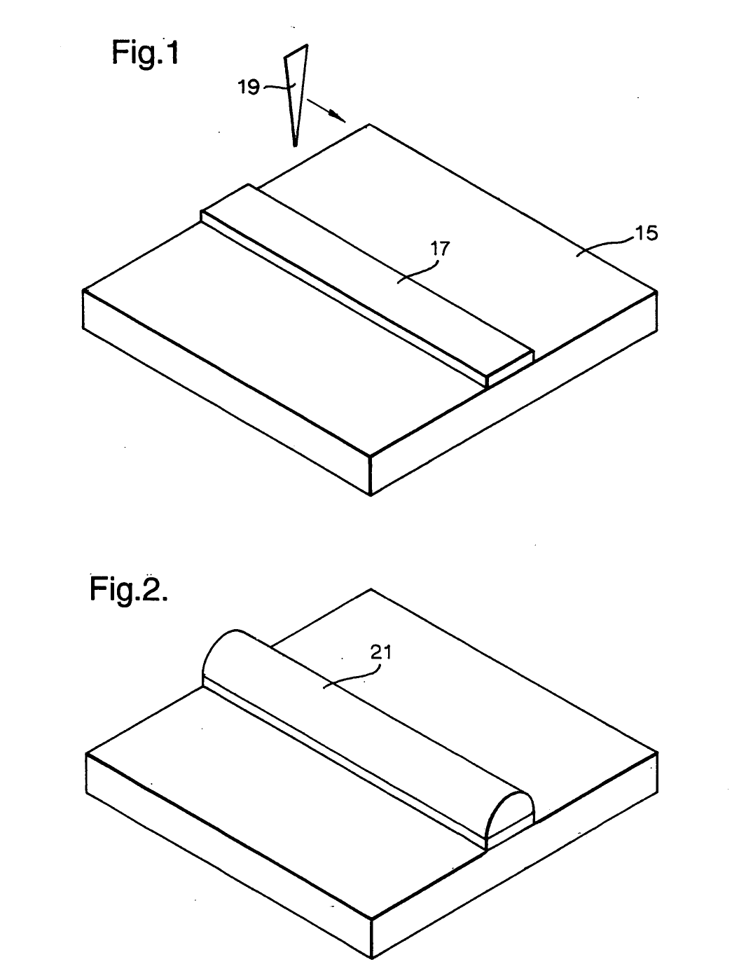

FIG. 1 shows the first stage of the two stage process according to the invention as applied to a substrate material to be used in an autocatalytic plating process.

FIG. 2 shows the final stage of depositing a metal plating on the substrate depicted in FIG. 1.

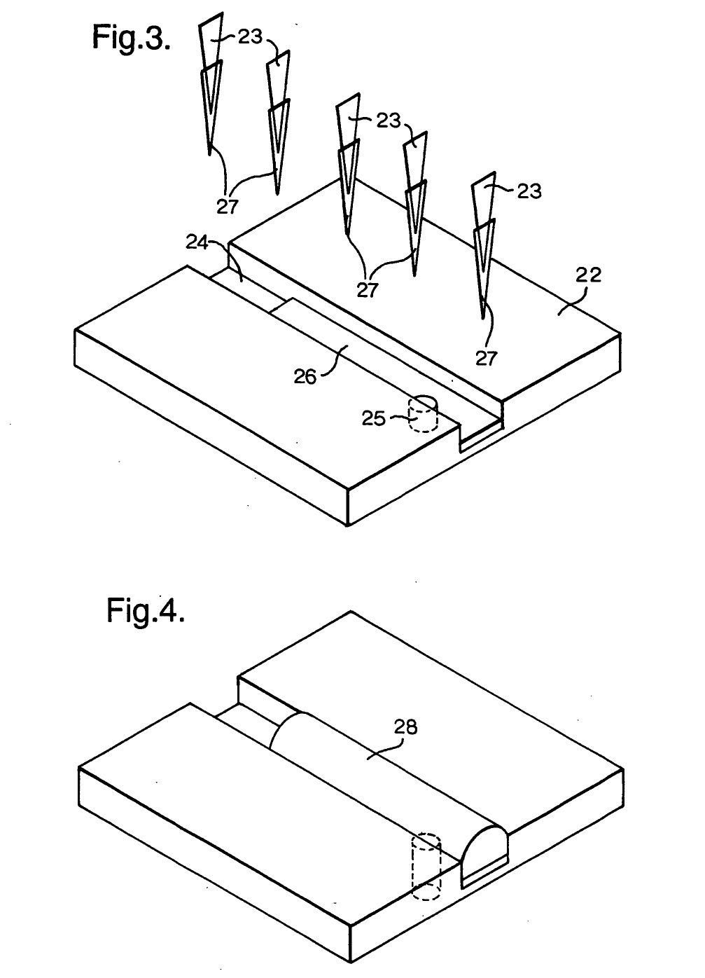

FIG. 3 shows the first stage of the two stage process according to the invention as applied to a substrate material containing surface features to be used in an autocatalytic plating process.

FIG. 4 shows the final stage of depositing a metal plating on the substrate within the features depicted in FIG. 3.

Turning to FIG. 1, a substrate 15 has been partially coated with a layer of catalytic material 17 which comprises an electroless deposition promoting material. The layer 17 has been applied via a suitable energetic media 19, for example a vacuum coating system containing an electron beam with the vapour phase of the deposition promoting material.

FIG. 2 shows the substrate material from FIG. 1 after it has been immersed in a suitable autocatalytic deposition solution bath. A metal 21 has now been deposited onto the layer 17.

Turning to FIG. 3, a substrate 22 has been scribed with the mechanism 23 to form a groove 24 and a hole 25 both of which are then coated with a layer of catalytic material 26 which comprises an electroless deposition promoting material. The layer 26 has been applied via a suitable energetic media 27, for example a vacuum coating system containing an electron beam with the vapour phase of the deposition promoting material.

FIG. 4 shows the substrate material from FIG. 3 after it has been immersed in a suitable autocatalytic deposition solution bath. A metal 28 has now been deposited onto the layer 26 so that the groove 24 and hole 25 are coated with the metal. The groove 24 also prevents the depositing metal from spreading sideways thus maintaining the desired aspect ratio of the deposit. The metal in the groove and hole are therefore also protected from mechanical damage by being contained beneath the surface of the substrate.

1-18 (Cancelled)

19. A method of depositing a metal onto a substrate in a user defined pattern by means of a catalytic reaction including the steps of
i) coating some or all of the substrate material with a catalytic material using a beam writing process to physically deposit the catalytic material onto the surface of the substrate in a pre-determined pattern;
ii) introducing the coated substrate into a liquid catalytic reaction bath such that the catalytic material catalyses the deposition of metal onto the coated areas of the substrate.

20. A process as claimed in claim 19 wherein the catalytic material is a catalytic metal.

21. A process as claimed in claim 20 wherein the catalytic metal is selected from the group consisting of nickel, cobalt, copper, palladium and iron.

22. A process as claimed in claim 19 wherein the catalytic material is a metal compound which is reduced to produce catalytic metal in the pre-determined pattern.

23. A process as claimed in claim 22 Wherein the metal compound is reduced by beam writing the compound in an atmosphere of a reducing gas.

24. A process as claimed in claim 19 wherein the catalytic material is a deposition promoting material.

25. A process as claimed in claim 24 wherein the deposition promoting material is SnCl₂.

26. A process as claimed in claim 19 wherein the beam writing process is selected from the group consisting of lasers, electron beams, ion beams, atomic beams, plasmas, atomic force microscopes and scanning tunnel microscopes.

27. A process as claimed in claim 19 wherein the catalytic material is deposited into subsurface features in the substrate.

28. A method of depositing a material onto a substrate in a user defined pattern by means of a catalytic reaction as claimed in claim 19 wherein steps (i) and (ii) are repeated in order to deposit multiple layers of material onto the substrate.

29. A method of depositing a material onto a substrate in a user defined pattern by means of a catalytic reaction as claimed in claim 28 wherein the multiple layers of material are each separated by at least one layer of insulating material

30. A method as claimed in claim 29 wherein the at least one layer of insulating material is deposited by a pattern transfer mechanism.

31. A method as claimed in claim 30 wherein the pattern transfer mechanism is ink-jet printing.

32. A method of plating a substrate with a metal coating over a pre-determined area of its surface by an autocatalytic deposition process comprising the steps of:
i) coating some or all of the substrate material with a catalytic metal in the predetermined pattern by a process including a beam writing step; and
iii) introducing the coated substrate into an autocatalytic solution comprising a metal salt and a reducing agent.

33. A method of metal plating a substrate by an autocatalytic deposition process as claimed in claim 32 comprising the further step of introducing the coated substrate from step (b) of claim 32 into a further autocatalytic solution comprising a further metal salt and a reducing agent.

34. A method of metal plating a substrate by an autocatalytic deposition process as claimed in claim 32 comprising the further step of introducing the coated substrate material from step (b) of claim 32 into an electrolytic bath in order to electrodeposit a further metal.

35. A method of metal plating a substrate by an autocatalytic deposition process as claimed in claim 32 wherein the autocatalytic solution contains two or more metals salts in solution.

36. A method of metal plating a substrate by an autocatalytic deposition process as claimed in claim 32 wherein the catalytic metal is deposited by reducing a metal compound with a deposition promoting material.

37. A method of metal plating a substrate by an autocatalytic deposition process as claimed in claims 36 wherein the deposition promoting material comprises an activator.

38. A method of metal plating a substrate by an autocatalytic deposition process as claimed in claim 37 wherein the activator is a surface coating of Pd derived by beam writing palladium metal.

39. A method of metal plating a substrate by an autocatalytic deposition process as claimed in claim 32 wherein the catalytic metal is formed by beam writing a metal-containing compound in an environment comprising a reducing gas.
